(19) United States
(12) Patent Application Publication
(10) Pub. No.: US 2026/0006785 A1
(43) Pub. Date: Jan. 1, 2026

(54) MEMORY CELL

(71) Applicants: CENTRE NATIONAL DE LA RECHERCHE SCIENTIFIQUE, pARIS (FR); STMicroelectronics (Crolles 2) SAS, Crolles (FR); STMicroelectronics S.r.l., Agrate Brianza (IT); STMicroelectronics (Rousset) SAS, Rousset (FR); UNIVERSITE D'AIX MARSEILLE, Marseille (FR)

(72) Inventors: Vincenzo Della Marca, Marseille (FR); Franck Melul, Aubagne (FR); Francesco La Rosa, Rousset (FR); Stephan Niel, Meylan (FR); Arnaud Regnier, Les Taillades (FR); Antonino Conte, Tremestieri Etneo (IT); Nadia Miridi, Auriol (FR)

(21) Appl. No.: 18/720,498

(22) PCT Filed: Dec. 15, 2021
(86) PCT No.: PCT/IB2021/000872

§ 371 Date: Jun. 14, 2024

(51) Int. Cl. H10B 41/30; G11C 16/04; G11C 16/10; G11C 16/14

(52) U.S. Cl. CPC H10B 41/30; G11C 16/0416; G11C 16/10; G11C 16/14

(57) ABSTRACT

The present disclosure relates to a memory cell (1) and to a method of erasing the memory cell (1). The memory cell comprises a doped well (100) of a first conductivity type and a transistor (T). Transistor (T) comprises a doped first region (106) of a second conductivity type opposite to the first conductivity type, the first doped region extending in the doped well (100); a buried doped channel (118) of the second conductivity type extending in the doped well (100); and a gate stack (108) resting on the doped well (100), above the buried doped channel (118). The gate stack (108) comprises a first layer (110) adapted to trap charges, a second insulating layer (112) resting on the first layer and a third conductive layer (114) resting on the second layer.

### CROSS-REFERENCE TO RELATED APPLICATIONS

This application is a national stage application of International Application No. PCT/IB2021/000872, filed on Dec. 15, 2021, which application is hereby incorporated herein by reference.

### TECHNICAL FIELD

The present disclosure relates generally to electronic devices and, more particularly, to electronic devices comprising a memory cell.

### BACKGROUND

Memory cells of the non-volatile type are known. These memory cells are reprogrammable. Among these non-volatile reprogrammable memory cells, there are memory cells called embedded Select in Trench Memory (eSTM). Non-volatile reprogrammable memory cells are, for example, implemented in memory circuits of the flash type.

### SUMMARY

Embodiments address all or some of the drawbacks of known non-volatile reprogrammable memory cells, and, for example, in particular of the eSTM memory cells.

One embodiment provides a memory cell comprising a doped well of a first conductivity type and a transistor. The transistor comprises a doped first region of a second conductivity type opposite to the first conductivity type. The first doped region extending in the doped well. A buried doped channel of the second conductivity type extends in the doped well. A gate stack is disposed on the doped well, above the buried doped channel. The gate stack comprises a first layer adapted to trap charges, a second insulating layer resting on the first layer and a third conductive layer resting on the second layer.

According to one embodiment, the first layer is disposed on a fourth insulating layer, the fourth insulating being disposed on the doped well, preferably in contact with the doped well.

According to one embodiment, the gate stack comprises a control gate comprising the second and third layers, and a floating gate comprising the first and fourth layers.

According to one embodiment, the buried doped channel extends from the first doped region.

According to one embodiment, the transistor comprises a doped second region of the second conductivity type extending in the doped well, the buried doped channel extending from the first region to the second region.

According to one embodiment, the memory cell further comprises a fifth doped layer of the second conductivity type, the doped well resting on and in contact with the fifth layer. A vertical gate is in contact with the doped well. The vertical gate vertically extends from a first face of the doped well at least up to a second face of the doped well. The second face is opposite to the first face and being in contact with the fifth layer.

According to one embodiment, the buried doped channel extends from the first region to the vertical gate.

According to one embodiment, the memory cell comprises a doped second region of the second conductivity type extending in the doped well, the buried doped channel extending from the first doped region to the second region and the second region being in contact with the vertical gate.

One embodiment provides a method for controlling the memory cell, e.g., as described above. The method comprises an erasing step during which a first potential is applied to the first region to make a current flowing through the buried doped channel so that hot carriers are generated in the buried doped channel, a second potential is applied to the doped well, and a third potential is applied to the third conductive layer of the gate stack so that an electric field between the doped well and the third conductive layer injects the generated hot carriers having a first polarity inside the first layer.

According to one embodiment, the memory cell further comprises a fifth doped layer of the second conductivity type, the doped well being disposed on and in contact with the fifth layer. A vertical gate is in contact with the doped well. The vertical gate vertically extends from a first face (102) of the doped well at least up to a second face of the doped well. The second face is opposite to the first face and is in contact with the fifth layer. The buried doped channel may extend from the first region to the vertical gate. The erasing step further comprises applying the second potential to the fifth layer and biasing the vertical gate so that the current flowing through the buried doped channel flows between the first region and the fifth layer, by flowing along the vertical gate.

According to one embodiment, a difference between the second and third potentials is about 10 V.

According to one embodiment, the first conductivity type is the P type and the first potential is in the range from 3 V to 7 V (for example, equal to 4.5 V), the second potential is a reference potential (for example, the ground), the third potential is in the range from −6 V to −12 V (for example, equal to −10 V), and a biasing potential in the range from 1 V to 5 V (for example, equal to 2.5 V) is applied to the vertical gate.

According to one embodiment, the method comprises a programming step during which a fourth potential is applied to the first region to make a current flowing through the transistor, under the gate stack and generating hot carriers, a fifth potential (for example, equal to the second potential) is applied to the doped well, and a sixth potential is applied to the third conductive layer of the gate stack, so that an electric field between the doped well and the third conductive layer injects the generated hot carriers having a second polarity inside the first layer.

According to one embodiment, the method comprises a reading step during which a same potential (for example, the ground) is applied to the third conductive layer and to the doped well, and a further potential is applied to the first region so that a current flows bellow the gate stack only if the memory cell is in an erased state.

One embodiment provides a device comprising a matrix of memory cells as previously described and a circuit configured to implement the above described method.

According to one embodiment, the circuit is further configured to erase one or several memory cells of the matrix with the Fowler Nordheim effect by applying a difference of potential between the doped well and the third conductive layer, for example, a difference of potential superior or equal to 20 V.

### BRIEF DESCRIPTION OF THE DRAWINGS

The foregoing features and advantages, as well as others, will be described in detail in the following description of specific embodiments given by way of illustration and not limitation with reference to the accompanying drawings, in which:

FIG. 1 is a schematic and sectional view of a memory cell according to one embodiment;

FIG. 2 illustrates an electronic device comprising a matrix of memory cells of FIG. 1;

FIG. 3 illustrates an example of two adjacent memory cells of the circuit of FIG. 2 according to one embodiment;

FIG. 4 illustrates an example of two adjacent memory cells of the circuit of FIG. 2 according to one other embodiment;

FIG. 5 illustrates a step of a method for controlling the memory cell of FIG. 1, according to one embodiment;

FIG. 6 illustrates another step of a method for controlling the memory cell of FIG. 1, according to one embodiment; and

FIG. 7 illustrates another step of a method for controlling the memory cell of FIG. 1, according to one embodiment.

### DESCRIPTION OF EMBODIMENTS

Like features have been designated by like references in the various figures. In particular, the structural and/or functional features that are common among the various embodiments may have the same references and may dispose identical structural, dimensional and material properties.

For the sake of clarity, only the operations and elements that are useful for an understanding of the embodiments described herein have been illustrated and described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless indicated otherwise, when reference is made to absolute positional qualifiers, such as the terms “front,” “back,” “top,” “bottom,” “left,” “right,” etc., or to relative positional qualifiers, such as the terms “above,” “below,” “higher,” “lower,” etc., or to qualifiers of orientation, such as “horizontal,” “vertical,” etc., reference is made to the orientation shown in the figures.

Unless specified otherwise, the expressions “around,” “approximately,” “substantially” and “in the order of” signify within 10%, and preferably within 5%.

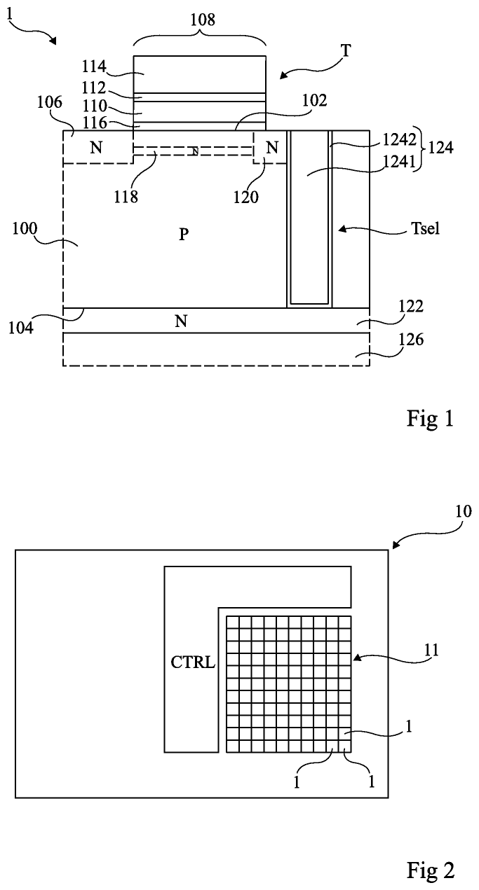

FIG. 1 is a schematic and sectional view of a memory cell 1 according to one embodiment. More particularly, in the example of FIG. 1, the memory cell 1 is an eSTM memory cell.

The memory cell 1 comprises a doped well 100. The well 100 is made of a semiconductor material, for example, of silicon. The well 100 is doped of a first conductivity type. In the example of FIG. 1, the well 100 is doped of the P type. The concentration of doping atoms in the well 100 is, for example, comprised between 1014 and 5×10¹⁵ at.cm\hat{ }(−3).

The well has a first face 102, the superior face in the orientation of FIG. 1, and a second face 104, the inferior face in the orientation of FIG. 1. The face 102 is opposite to face 104.

The memory cell 1 further comprises a transistor T.

The transistor T comprises a doped region 106, delimited by dotted lines in FIG. 1. The region 106 is made of a semiconductor material, for example, of silicon. The region 106 is doped of a second conductivity type, which is opposite to the first conductivity type. In the example of FIG. 1, the region 106 is doped of the N type. The concentration of doping atoms in the region 106 is, for example, superior to the concentration of doping atoms in the P-type doped well 100. The concentration of doping atoms in the region 106 is, for example, comprised between 10¹⁸ and 10²⁰ at.cm³.

The region 106 extends in the doped well 100. For example, the region 106 penetrates in the doped well 100 from the face 102. For example, the region 106 is made by implanting doping atoms in the doped well 100, at the emplacement of the region 106.

The region 106 forms, or belongs to, a conduction region of the transistor T, that is the drain or the source of the transistor T. In the example of FIG. 1, the region 106 forms, or belongs to, the drain of transistor T.

The transistor T further comprises a gate stack 108. The gate stack 108 is disposed on the doped well 100. Said in other words, the gate stack 108 overlaps a part of the doped well 100. Said in yet other words, the gate stack 108 overlies the doped well 100. More precisely, the gate stack 108 is disposed on and in contact with the doped well 100. Said in other words, the gate stack 108 overlies and in contact with the face 102 of the doped well 100.

The gate stack 108 comprises a layer 110 adapted to trap charges, for example, a layer 110 configured to trap charges.

The gate stack 108 further comprises an insulating layer 112. The layer 112 overlies the layer 110, for example, in contact with the layer 110. The insulating layer 112 is, for example, made of a single layer, for example, of silicon oxide. As an alternative, the insulating layer 112 is, for example, made of a stack of insulating layers, for example, successively comprising a silicon oxide layer, a silicon nitride layer and a silicon oxide layer.

The gate stack 108 further comprises a conductive layer 114. The layer 114 overlies the layer 112, for example, in contact with the layer 112. The layer 114 is, for example, made of one or several metals and/or of one or several semiconductors. For example, layer 114 is made of polycrystalline silicon.

The layer 110 overlies an insulating layer 116, for example, in contact with the insulating layer 116. The layer 116 of the gate stack 108 overlies the doped well 100, for example, in contact with the doped well 100. The layer 110 is, for example, made of one or several metals and/or of one or several semiconductors. For example, layer 110 is made of the same material as layer 114. As an alternative example, layer 110 comprises nanocrystals adapted to trap charges.

As another alternative example, layer 110 is made of silicon nitride material adapted to trap charges.

In the example of FIG. 1, the gate stack 108 comprises a floating gate comprising the layers 110 and 116, and a control gate comprising the layers 112 and 114.

The region 106 may at least partly extend below the gate stack 108.

The transistor T further comprises a buried doped channel 118, delimited in dotted lines in FIG. 1.

The buried channel is made of a semiconductor material, for example, of silicon. The buried channel 118 is doped of the second conductivity type, that is, the N-type in the example of FIG. 1. For example, the concentration of doping atoms in the buried channel 118 is comprised between 10¹⁷ and 10¹⁹ at.cm³. For example, in case the channel 118 is N-doped, the doping atoms in the channel 118 are arsenic atoms.

The buried doped channel 118 extends below the gate stack 108. The buried doped channel 118 extends in the P-doped well 100. For example, the buried channel 118 is disposed below the face 102 of the doped well 100, and is separated from the face 102 of the doped well 100 by a portion of the well 100 which is doped of the first conductivity type, that is the P-type in the example of FIG. 1. Preferably, the gate stack 108 entirely overlaps the buried channel 118.

For example, the buried channel 118 comprises a doped layer of the second conductivity type. For example, the doped layer or channel 118 extends parallel to the face 102 of the doped well 100.

The buried doped channel 118 extends from the region 106. The buried channel 118 contacts the region 106.

According to one embodiment, as illustrated in FIG. 1, the buried doped channel 118 extends from the region 106 to a doped region 120, delimited in dotted lines in FIG. 1, the buried channel 118 being in contact with both regions 106 and 120. The region 120 is made of a semiconductor material, for example, of silicon. The region 120 extends in the doped well 100. For example, the region 120 penetrates in the doped well 100 from the face 102. The region 120 is doped of the second conductivity type, that is, the N-type is the example of FIG. 1. The concentration of doping atoms in the region 120 is, for example, comprised between 10¹⁸ and 10²⁰ at.cm³. For example, the region 120 is made by implanting doping atoms in the doped well 100, at the emplacement of the region 120.

In the example of FIG. 1, the transistor T comprises the region 120. The region 120 then forms, or belongs to, a conduction region (drain or source) of the transistor T. In the example of FIG. 1, the region 120 forms, or belongs to, the source of transistor T.

The region 120 may at least partly extends below the gate stack 108.

In the example of FIG. 1, the memory cell 1 is an eSTM memory cell and further comprises a doped layer 122 and a vertical gate 124.

The doped layer 122 is doped of the second conductivity type, that is, of the N-type in the example of FIG. 1. The doped layer 122 is made of a semiconductor, for example, of silicon. For example, the concentration of doping atoms in the layer 122 is comprised between 10¹⁷ and 10¹⁹ at.cm³.

The doped well 100 overlies the layer 122, for example, in contact with the layer 122. For example, the well 100 overlies and is in contact with the layer 122.

As an example, the layer 122 overlies a substrate 126, for example, a semiconductor substrate, for example, a silicon substrate. The substrate 126 is, for example, doped with the first conductivity type.

The vertical gate 124 is in contact with the doped well 100, for example, with a lateral face of the well 100, the lateral face extending perpendicular to the faces 102 and 104 of the well 100.

The vertical gate 124 extends from the face 102 of the well 100 at least up to the face 104 of the well 100. In the example of FIG. 1, the vertical gate 124 extends from the face 102 to the face 104 and does not penetrate the layer 122. In another example, which is not illustrated, the vertical gate 124 penetrates in the layer 122.

The vertical gate 124 is disposed on the side of a first edge of the gate stack 108 (on the right in FIG. 1) and the region 106 is disposed on the side of a second edge of the stack 108 (on the left in FIG. 1), the first and second edges being opposite to each other. Said in other words, the gate stack 108 extends between the region 106 and the vertical gate 124.

The vertical gate 124 comprises, for example, a conductive core 1241 and an insulating shell 1242. The insulating shell 1242 separates the core 1241 from the well 100 and the layer 122. The insulating shell 1242 comprises, for example, one or several insulating layers. The shell 1242 is, for example, made of silicon oxide. The conductive core 1241 comprises, for example, a metal and/or a doped semiconductor. The conductive core 1241 is, for example, made of polycrystalline silicon.

The buried doped channel 118 extends between the region 106 and the vertical gate 124. Said in other words, the buried channel 118 extends from the region 106 toward the vertical gate 124.

According to one embodiment in which transistor T comprises the region 120 doped of the second conductivity type, as illustrated by FIG. 1, the vertical gate 124 is in contact with the region 120. Said in other words, the region 120 extends from the vertical gate 124 to the buried channel 118, region 120 being in contact with buried channel 118 and the vertical gate 124, for example, in contact with layer 1242.

According to an alternative embodiment (not shown on FIG. 1), the region 120 is omitted. In this case, the buried channel 118 extends up to the vertical gate 124, for example, up to the layer 1242. In this alternative embodiment, the gate stack 108 extends up to the vertical gate 124, and may at least partly overlap the vertical gate 124.

In the example of FIG. 1, the eSTM memory cell 1 thus comprises a transistor Tsel comprising the layer 122, the vertical gate 124 and the region 120, the region 120 and the layer 122 corresponding, for example, to the source and drain regions of the transistor Tsel. In the example of FIG. 1 where the well 100 is P-doped, the region 120 corresponds to the drain of the transistor Tsel and the layer 122 corresponds to the source of the transistor Tsel.

According to an embodiment, for example illustrated by FIG. 2, a memory circuit 10 comprising a memory cell 1 is provided. More particularly, in the example of FIG. 2, the memory circuit, or device, 10 comprises a matrix 11 of memory cells 1, organized in rows and columns. As an example, the sectional view of the FIG. 1 is taken in a direction parallel to a row of memory cells 1 of the matrix 11.

The memory circuit 10 further comprises a circuit CTRL for controlling the memory cells 1 of the circuit 10. For example, the control circuit CTRL is configured to provide signals, or, said in other words, to apply potentials to the cells 1 in order to control the cells 1, for example, in order to implement steps of reading, programming and/or erasing the cells 1. In particular, as it is usual in a matrix of memory cells, the circuit CTRL may provide at least one signal simultaneously to all the cells 1 of a given column, and/or at least one signal simultaneously to all the cells 1 of a given row.

As an example, two adjacent memory cells 1 of the same row may share the same vertical gate 124, the two memory cells being, for example, symmetrical with respect to the vertical gate 124.

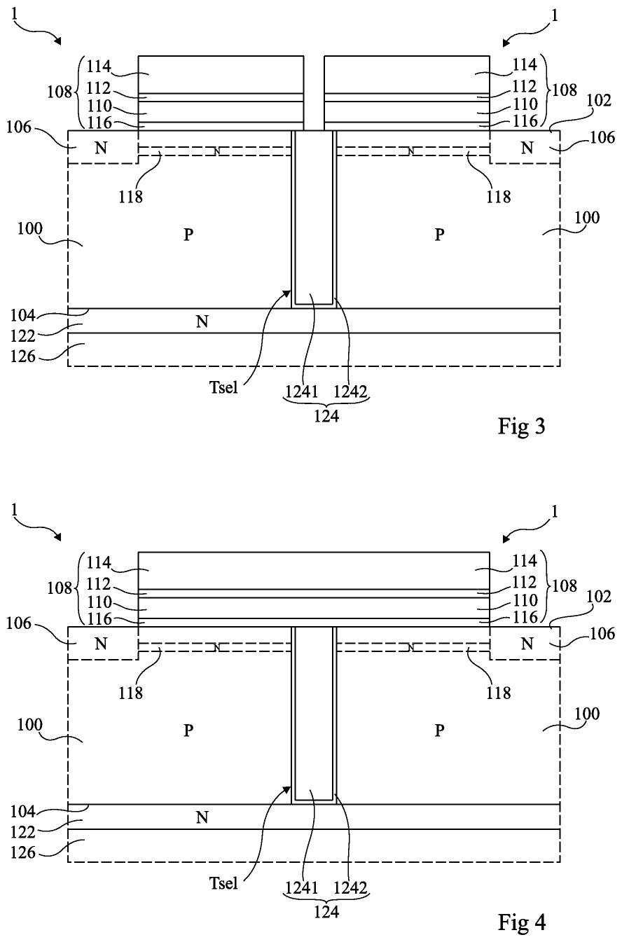

In case of two adjacent memory cells 1 of the same row sharing the same vertical gate 124, each of the two cells 1, for example, has its own gate stack 108, which is separated and insulated from the gate stack 108 of the other cell 1 as illustrated by FIG. 3.

FIG. 3 illustrates an example of two adjacent cells 1 sharing the same vertical gate 124, in which each of the two cells 1 has its own gate stack 108.

In the FIG. 3 example, the gate stack 108 of each of the two adjacent cells 1 partly overlaps the vertical gate 124 common to the two cells. As represented in FIG. 3, as the gate stack 108 of each of the two cells 1 overlaps the vertical gate 124 of the cell 1, the region 120 is, for example, omitted.

In another example. which is not shown, of two cells 1 sharing the same vertical gate 124 but having each its own gate stack 108, in each of the two cells 1, the gate stack 108 does not overlaps the vertical gate 124 and the region 120 is provided, as illustrated for one cell 1 in FIG. 1.

Furthermore, two adjacent memory cells 1 of the same row sharing the same vertical gate 124 may also share the same gate stack 108, as, for example, illustrated by FIG. 4.

FIG. 4 illustrates another example of two adjacent cells 1 sharing the same vertical gate 124, in which the two cells 1 also share the same gate stack 108. In FIG. 4 example, the gate stack 108 which is common to the two adjacent cells 1 overlaps the vertical gate 124 common to the both cells 1. In each of the two cells 1, as the gate stack 108 overlaps the common vertical gate 124, the region 120 is, for example, omitted.

As an example, layer 110 is made of a semiconductor material. In such an example, the two adjacent cells 1 may store only one bit of data.

As an alternative example, layer 110 is made of nanocrystals or a silicon nitride layer, and it is possible for the two adjacent cells 1 to store two bits of data, one in each cell 1.

Referring back to FIG. 1 and FIG. 2, as an example not illustrated, two adjacent memory cells 1 of the same row may share the same region 106, the two memory cells being, for example, symmetrical with respect to the region 106.

As an example, the layer 122 may be shared by a plurality of memory cells 1, for example, by more than two memory cells 1. This is, for example, the case in the example illustrated by FIG. 3.

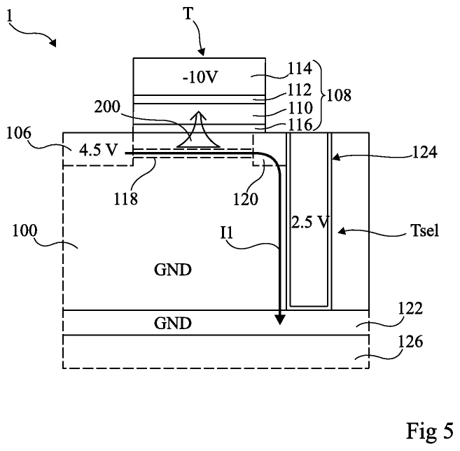

FIG. 5 illustrates a step of a method for controlling the memory cell of FIG. 1, according to one embodiment.

More particularly, FIG. 5 illustrates a step of erasing the memory cell 1 of FIG. 1, in an example where the well 100 is P-doped. It is here considered, as an example, that the memory cell 1 has been previously programmed and that charges, in this example, electrons, are trapped in the layer 110. Said in other words, in this example, the layer 110 is negatively charged before the erasing step.

During the erasing step, the same reference potential, for example, the ground potential GND, is applied to the doped well 100 and the layer 122.

During the erasing step, a potential is applied to the region 106 so that a current I1 flows in the transistor T, and, more particularly, though, or via or in, the buried channel 118.

As the memory cell 1 is an eSTM memory cell, in order to make the current I1 flowing in the transistor T, the vertical gate 124 and the layer 122 are biased so that the current I1 flows between region 106 and layer 122, and, in particular, flows along the vertical gate 124. For example, the potential applied to the region 106 is comprised between 3 and 7 V and is, for example, approximatively equal to 4.5 V, when the reference potential is the ground potential GND, that is the null potential. For example, the potential applied to the vertical gate 124 is comprised between 1 and 5 V, and is, for example, approximatively equal to 2.5 V, when the reference potential is the ground potential GND.

The current I1 flowing through the channel 118 generates hot carriers thanks to the doping atoms in the channel 118 and in region 106. In the example of FIG. 5 where the channel 118 is N-type doped, the current I1 generates hot electrons. These hot electrons in turn generate highly energetic electron/hole pairs, or, said in other words, further hot carriers. These further generated hot carriers are, for example, named “secondary hot carriers” by opposition to the hot carriers directly generated by the current I1, which are named “primary hot carriers”.

Further, a potential is applied to the layer 114 so that the difference of potential between layer 114 and doped well 100 results in an electric field which injects, inside the layer 110, the generated hot carriers having a polarity opposite to the polarity of the charges trapped in the layer 110. By doing this, the injected hot carriers recombine with the charges stored in the layer 110 which have a polarity opposite to that of the injected hot carrier, leading to a suppression of these stored charges. The injection of these hot carriers inside the layer 110 is represented by an arrow 200 in FIG. 2. In this example, the injected hot carriers are hot holes, and, more particularly, secondary hot holes.

The potential difference between layer 122 and layer 114 is, for example, comprised between 6 and 12 V, for example, approximatively equal to 10 V. For example, the potential of the layer 114 is, for example, equal to −10 V when the reference potential is the ground potential GND.

An advantage of the memory cell 1, and in particular of the provision of the buried doped channel 118 in the memory cell 1, is that the erasing of the memory cell is done using a relatively low difference of potential between layer 114 and well 100 compared to the case of similar memory cell which does not comprise the buried channel.

Indeed, without the buried channel 118, the erasing step of the cell 1 is based on the Fowler Nordheim effect. Fowler Nordheim effect requires a relatively high difference of potential between the layer 114 and the well 100 compared to the case of the memory cell 1, for example, a difference of potential superior or equal to 20 V, in order to produce an electric field between the layer 114 and the doped well 100 which is sufficient for ejecting the charges stored in the layer 114 to the doped well 100 until there is no stored charge left in the layer 114.

An advantage of the memory cell 1 is that the implementation of the erasing step described in relation with FIG. 5 is independent of the thickness of the layer 116, which is not the case in an erasing step based on the Fowler Nordheim effect.

An advantage of the memory cell 1 is that the erasing step described in relation with FIG. 5 is completed only if the transistor Tsel is on, whereas is not the case in a similar memory cell having no channel 118 and being erased based on the Fowler Nordheim effect.

An advantage of the memory cell 1 is that the erasing step described in relation with FIG. 5 is faster, for example, at least 5 times faster, than an erasing step using the Fowler Nordheim effect in a similar memory cell which has no channel 118. For example, the duration of the erasing step in the memory cell 1 is about 20 us.

A further advantage of the memory cell 1 is that memory cell 1 stays compatible with an erasing step based on the Fowler Nordheim effect.

For example, in the circuit 10 of FIG. 2, the cells 1 of the matrix 11 can be erased using the erasing step described in relation with FIG. 5 and using the Fowler Nordheim effect.

For example, during a first phase of the lifetime of the circuit 10, which, for example, corresponds to a given number of erases of the matrix 11, the cells 1 are erased using the erasing step described in relation with FIG. 5, and during a second phase of the lifetime of the circuit 10, which begins when the first phase ends, the cells 1 are erased using the Fowler Nordheim effect.

As an alternative example, the cells 1 are erased using the Fowler Nordheim effect during the first phase of the lifetime of the circuit 10, and using the erasing step described in relation with FIG. 5 during the second phase of the lifetime of the circuit 10.

As a further alternative example, the cells 1 are erased by alternating one erasing phase using Fowler Nordheim effect and one erasing phase as described in relation with FIG. 5.

More generally, the erasing steps of the cells 1 of the matrix 11 may comprise, further to at least one erasing step as described in relation with FIG. 5, at least one erasing step using the Fowler Nordheim effect. Said in other words, several erasing steps of the cells 1 of the matrix 11 may comprise erasing steps as described in relation with FIG. 5 above, mixed with erasing steps using Fowler Nordheim effect.

An advantage of using erasing steps as described in relation with FIG. 5 and erasing steps using the Fowler Nordheim effect is that cells 1 sharing the same gate stack 108 and the same doped well 100 are erased simultaneously when the erasing step is based on the Fowler Nordheim effect, no matter what the potential applied on their vertical gates 124 is, and that each cells 1 of these plurality of cells 1 is erased only if its vertical gate 124 is correctly biased when the erasing step is as described in relation with FIG. 5. Thus, using erasing steps of the both types allows to choose the granularity of the erasing step for a plurality of cells 1, for example, a plurality of cells 1 sharing the same gate stack 108 and the same doped well 100.

Each erasing step of one or several cells 1 of the matrix 11 are, for example, implemented by the circuit CTRL (FIG. 2), whatever the erasing steps are only of the type described in relation with FIG. 5, or also comprise erasing steps based on the Fowler Nordheim effect.

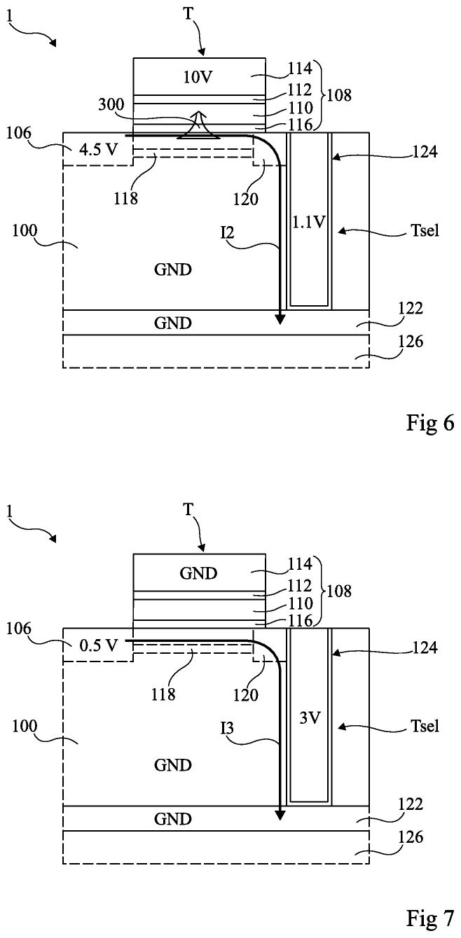

FIG. 6 illustrates another step of a method for controlling the memory cell 1 of FIG. 1, according to one embodiment.

More particularly, FIG. 6 illustrates a step of programming the memory cell 1 of FIG. 1, in an example where the well 100 is P-doped.

During the programming step, the same reference potential, for example, the ground potential GND, is applied to the layer 114, the doped well 100 and the layer 122.

During the programming step, a potential is applied to the region 106 so that a current I2 flows in the transistor T, below the gate stack 108.

As the memory cell 1 is an eSTM memory cell, in order to make the current I2 flowing in the transistor T, the vertical gate 124 and the layer 122 are biased so that the current 12 flows between region 106 and layer 122, and, in particular, flows along the vertical gate 124. For example, the potential applied to the region 106 is comprised between 3 and 7 V and is, for example, approximatively equal to 4.5 V, when the reference potential is the ground potential GND. For example, the potential applied to the vertical gate 124 is comprised between 1 and 2 V, and is, for example, approximatively equal to 1.1 V, when the reference potential is the ground potential GND.

The current I2 flowing through the channel 118 generates hot carriers, and, more particularly in the example of FIG. 6, hot electrons.

Further, a potential is applied to the layer 114 and another potential is applied to the doped well 100 so that the difference of potential between layer 114 and doped well 100 results in an electric field which injects, inside the layer 110, the generated hot carriers having a polarity opposite to the polarity of the charges injected in the layer 110 during an erasing step. The injection of these hot carriers inside the layer 110 is represented by an arrow 300 in FIG. 6. In this example, the injected hot carriers are hot electrons, for example, primary hot electrons.

The potential difference between layer 122 and layer 114 is, for example, comprised between 8 and 15 V, for example, approximatively equal to 10 V. For example, the doped well is biased with the reference potential, in this example the ground potential GND. In the example of FIG. 2, the potential of the layer 114 is, for example, equal to 10 V when the reference potential is the ground potential.

More generally, the potentials applied to the region 106, the doped well 100, the layer 122, the layer 114 and the vertical gate 124 are such that a phenomenon of injection of hot carriers appears in the memory cell 1, and that hot carriers (hot electrons in this example) are injected inside the layer 110.

FIG. 7 illustrates another step of a method for controlling the memory cell 1 of FIG. 1, according to one embodiment.

More particularly, FIG. 7 illustrates a step of reading the memory cell 1 of FIG. 1, in an example where the well 100 is P-doped.

During the reading step, the same reference potential, for example, the ground potential GND, is applied to the layer 114, the doped well 100 and the layer 122.

Further, a potential is applied to the region 106 so that a current 13 flows in the transistor T, below the gate stack 108, only if the memory cell 1 is in an erased state, or, said in other word, only if the reading step is performed whereas no programming step has been performed since the last erasing step.

As the memory cell 1 is an eSTM memory cell, in order to make the current 13 flowing in the transistor T when the memory cell 1 is in an erased state, the vertical gate 124 and the layer 122 are biased so that the current 13 flows between region 106 and layer 122, and, in particular, flows along the vertical gate 124.

For example, the potential applied to the region 106 is comprised between 0.1 and 1 V, and is, for example, approximatively equal to 0.5 V when the reference potential is the ground potential GND. For example, when the reference potential is the ground potential GND, the potential applied to the vertical gate 124 is comprised between 2 and 4 V and is, for example, approximatively equal to 3 V.

Furthermore, the potential applied to the region 106 during a reading step is such that no current 13 flows in the transistor T when the memory cell 1 is in a programmed state, or said, in other words, when the reading step is performed whereas no erasing step has been performed since the last programming step.

Thus, depending on whether the current 13 flows in the transistor T or not, it is determined whether the memory cell is in the programmed state or in the erased state, or, said in other words, which is the value of a bit stored in the memory cell 1 between a first value, for example, ‘0’, or a second value, for example, ‘1’.

Those skilled in the art can modify the values of the different potentials applied to the memory cell 1 during the respective steps of programming, erasing and reading the memory cell 1, for example, when the reference potential is not the ground potential GND.

Although not illustrated, all the conductivity types of the memory cell 1 may be inverted. In this case, the hot carriers injected in layer 110 are hot holes during the programing step and are secondary hot electrons during the erasing step described in relation with FIG. 5. In this case, those skilled in the art are capable of adapting in consequence the potentials applied to the memory cell 1 during the reading, programming and erasing phase, for example, by inverting the polarity of the potentials with respect to reference potential compared with what has been described in relation with FIGS. 5, 6 and 7. For example, in a memory cell 1 wherein all the conductivity types have been inverted compared to the example of FIG. 1, during an erasing phase of the memory cell 1 where the reference potential is the ground potential GND, the potential applied to the region 106 is comprised between −-3 and −7 V and is, for example, equal to −4.5 V, the potential applied to the layer 114 is comprised between 6 and 12 V and is, for example, equal to 10 V, and the potential applied to the vertical gate 124 is comprised between −1 and −5 V and is, for example, equal to −2.5 V.

Various embodiments and variants have been described. Those skilled in the art will understand that certain features of these embodiments can be combined and other variants will readily occur to those skilled in the art.

In particular, although the memory cell 1 is an eSTM memory cell comprising the layer 122 and the vertical gate 124, those skilled in the art are capable of adapting the present disclosure to other non-volatile programmable memory cells comprising the doped well 100, the region 106, the buried doped channel 118 and the gate stack 108 but being lacking layer 122 and vertical gate 124. Such a memory cell, for example, differs from the eSTM memory cell 1 in that the transistor Tsel is planar with a gate stack resting on the doped well 100 instead of being vertical with the vertical gate 124. Those skilled in the art are capable of applying potentials to such another memory cells to which the present disclosure applies, so that the erasing step of this memory cells results from the injection of secondary hot carriers in the layer 110, the secondary hot carriers being generated by a current flowing through the buried channel 118.

Finally, the practical implementation of the embodiments and variants described herein is within the capabilities of those skilled in the art based on the functional description provided hereinabove.

1-16. (canceled)

17. A memory cell comprising a doped well of a first conductivity type and a transistor, the transistor comprising:
a doped first region of a second conductivity type opposite to the first conductivity type, the first doped region disposed in the doped well;
a buried doped channel of the second conductivity type extending in the doped well; and
a gate stack overlying the doped well above the buried doped channel, the gate stack comprising a first layer adapted to trap charges, a second insulating layer overlying the first layer, and a third conductive layer resting on the second layer.

18. The memory cell of claim 17, wherein the first layer overlies a fourth insulating layer, the fourth insulating layer overlying the doped well.

19. The memory cell of claim 18, wherein the fourth insulating layer is in contact with the doped well.

20. The memory cell of claim 18, wherein the gate stack comprises a control gate comprising the second and third layers and a floating gate comprising the first and fourth layers.

21. The memory cell of claim 17, wherein the buried doped channel is spaced from the gate stack by a portion of the doped well.

22. The memory cell of claim 17, wherein the transistor comprises a doped second region of the second conductivity type disposed in the doped well, the buried doped channel extending from the first region to the second region.

23. The memory cell of claim 17, wherein the memory cell further comprises:
a fifth doped layer of the second conductivity type, the doped well overlying and in contact with the fifth layer; and
a vertical gate vertically extending from a first face of the doped well at least up to a second face of the doped well, the second face being opposite to the first face and being in contact with the fifth layer.

24. The memory cell of claim 23, wherein the buried doped channel extends from the first region to the vertical gate.

25. The memory cell of claim 23, wherein the memory cell comprises a doped second region of the second conductivity type disposed in the doped well and in contact with the vertical gate, the buried doped channel extending from the first doped region to the second region.

26. A device comprising:
a matrix of memory cells according to claim 17; and
a control circuit further configured to erase one or more of the memory cells of the matrix with the Fowler Nordheim effect by applying a difference of potential between the doped well and the third conductive layer.

27. The device of claim 26, wherein the control circuit is configured to perform an erasing step, a programming step, and a reading step;
wherein the erasing step comprises applying a first potential to the first region to cause a current to flow through the buried doped channel so that hot carriers are generated in the buried doped channel, and applying a second potential to the doped well and a third potential to the third conductive layer of the gate stack so that an electric field between the doped well and the third conductive layer injects the generated hot carriers of a first polarity in the first layer;
wherein the programming step comprises applying a fourth potential to the first region to cause a current flowing under the gate stack thereby generating hot carriers, and applying a fifth potential to the doped well and a sixth potential to the third conductive layer of the gate stack, so that an electric field between the doped well and the third conductive layer injects the generated hot carriers of a second polarity in the first layer; and
wherein the reading step comprises applying the same potential to the third conductive layer and to the doped well, applying a further potential to the first region, and determining whether a current flows below the gate stack.

28. A method for controlling a memory cell that comprises a doped first region of a second conductivity type disposed in a doped well of a first conductivity type, a buried doped channel of the second conductivity type extending in the doped well, and a gate stack overlying the doped well above the buried doped channel and comprising a first layer, a second insulating layer overlying the first layer, and a third conductive layer resting on the second layer, the method comprising:
applying a first potential to the first region to cause a current to flow through the buried doped channel so that hot carriers are generated in the buried doped channel; and
applying a second potential to the doped well and a third potential to the third conductive layer of the gate stack so that an electric field between the doped well and the third conductive layer injects the generated hot carriers in the first layer.

29. The method of claim 28, wherein a difference between the second and third potentials is about 10 V.

30. The method of claim 28, wherein the memory cell further comprises a fifth doped layer of the second conductivity type and a vertical gate vertically extending from a first face of the doped well to a second face of the doped well, the second face being opposite to the first face and being in contact with the fifth layer, wherein the buried doped channel extends from the first region to the vertical gate;
wherein applying the second potential comprises applying the second potential to the fifth layer; and
the method further applying a biasing potential to the vertical gate so that the current flowing through the buried doped channel flows between the first region and the fifth layer.

31. The method of claim 30, wherein the first conductivity type is P type;
wherein the first potential is in the range from 3 V to 7 V;
wherein the second potential is a reference potential;
wherein the third potential is in the range from −6 V to −12 V; and
wherein the biasing potential is in the range from 1 V to 5 V.

32. The method of claim 30, wherein the first conductivity type is P type;
wherein the first potential is about 4.5 V;
wherein the second potential is 0 V;
wherein the third potential is about −10 V; and
wherein the biasing potential is about 2.5 V.

33. The method of claim 28, wherein the method further comprises:
applying a fourth potential to the first region to cause a current flowing under the gate stack thereby generating hot carriers; and
applying a fifth potential to the doped well and a sixth potential to the third conductive layer of the gate stack, so that an electric field between the doped well and the third conductive layer injects the generated hot carriers having a second polarity in the first layer;
wherein applying the second and third potentials causes hot carriers of a first polarity to be injected in the first layer; and
wherein applying the fifth and sixth potentials causes hot carriers of a second polarity to be injected in the first layer.

34. The method of claim 28, further comprising:
applying the same potential to the third conductive layer and to the doped well;
applying a further potential to the first region; and
determining whether a current flows below the gate stack.

35. A method for controlling a memory cell that comprises an n-type doped first region disposed in a p-type doped well, an n-type doped buried channel extending into the doped well, and a gate stack overlying the doped well above the buried doped channel and comprising a first layer, a second insulating layer overlying the first layer, and a third conductive layer resting on the second layer, the method comprising:
applying a first potential to the first region, wherein the first potential is in the range from 3 V to 7 V;
applying a reference potential to the doped well; and
applying a third potential to the third conductive layer of the gate stack, wherein the third potential is in the range from −6 V to −12 V.

36. The method of claim 35, wherein the difference between the reference potential and the third potential is about 10 V.

37. The method of claim 35, wherein the memory cell further comprises a fifth n-type doped layer and a vertical gate vertically extending from a first face of the doped well to a second face of the doped well, the second face being opposite to the first face and being in contact with the fifth layer, wherein the buried doped channel extends from the first region to the vertical gate, the method further comprising:
applying the reference potential to the fifth layer; and
applying a biasing potential to the vertical gate, wherein the biasing potential is in the range from 1 V to 5 V.
